(19) United States
(12) Patent Application Publication
(10) Pub. No.: US 2024/0412799 A1
(43) Pub. Date: Dec. 12, 2024

(54) Circuits And Methods For Memory Built-In-Self-Tests

(71) Applicant: Altera Corporation, San Jose, CA (US)

(72) Inventors: Kok Wah Khor, Nibong Tebal (MY); Rajiv Kumar, Tanjung Tokong (MY)

(73) Assignee: Altera Corporation, San Jose, CA (US)

(21) Appl. No.: 18/809,696

(22) Filed: Aug. 20, 2024

(51) Int. Cl. G11C 29/36; G11C 7/10; G11C 29/12

(52) U.S. Cl. CPC G11C 29/36; G11C 7/1036; G11C 29/1201

(57) ABSTRACT

An integrated circuit includes memory circuits, a selector circuit, a bus coupled to the selector circuit, and a controller circuit. The controller circuit provides test signals from the controller circuit through the bus to the selector circuit for transmission to the memory circuits during a memory built-in-self-test mode. Each of the memory circuits can include a comparator circuit configurable to compare a read data bit read from one of the memory circuits to an expected data bit in the test signals to generate a sticky error bit during the memory built-in-self-test mode.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a diagram that illustrates an example of a portion of an integrated circuit (IC) that can test memory circuits in the IC using a memory built-in-self-test (MBIST) controller circuit and a network-on-chip (NOC) bus.

FIG. 2 is a diagram that illustrates further details of circuits in a sector and the control circuit in the IC of FIG. 1.

FIG. 3 is a diagram that illustrates examples of a memory core circuit and comparator circuits that can be in each of the memory circuits in the sectors of the integrated circuit (IC) of FIG. 1.

FIG. 4 is a diagram that illustrates details of examples of circuits that can be in each of the memory circuits in an IC to enable a memory built-in-self-test (MBIST) of the memory circuits during an MBIST mode.

FIG. 5 is a diagram that illustrates an example of a configurable logic integrated circuit (IC).

FIG. 6A is a block diagram of a system that can be used to implement a circuit design to be programmed into a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

### DETAILED DESCRIPTION

In a system-on-chip (SoC), hardened memory built-in-self-test (MBIST) controllers are used to test memory blocks. To achieve at-speed testing, one MBIST controller using one or a few memory macros is usually implemented. MBIST area is costly when there are many memory macros in the SoC.

In a field programmable gate array (FPGA), memory blocks are scattered around the integrated circuit (IC) die. As an example, a large FPGA IC can have thousands of memory blocks. Multiple MBIST controllers may be used to test an FPGA memory array.

For functional safety (FUSA) automotive requirements that require memory arrays in an FPGA to be tested during power on, a custom configurable MBIST controller is built in a custom circuit design for the FPGA. However, using a configurable MBIST controller is time consuming. Also, it is difficult to meet at-speed frequency testing requirements using a configurable MBIST controller. In addition, a configurable MBIST controller consumes resources on an FPGA for both manufacturing tests and the custom circuit design.

According to some examples disclosed herein, techniques are provided for using a single memory built-in-self-test (MBIST) controller circuit to test many memory circuits in an integrated circuit (IC) concurrently. According to these examples, an IC includes an MBIST controller circuit that generates MBIST signals during an MBIST mode. The MBIST signals are sent through a high-speed pipelined network-on-chip (NOC) bus for transmission to the memory circuits in the IC when the MBIST mode is enabled. The MBIST mode is enabled by test control signals. Comparators and storage circuitry in the memory circuits generate and capture sticky error bits during the MIBIST mode and shift out the sticky error bits to output pads of the IC. The NOC can also be used to transmit configuration bits (i.e., configuration data bits) to configurable logic circuits and/or to the memory circuits in the IC during a configuration mode of the IC. Using the NOC for transmission of both configuration bits and MBIST signals reduces circuit area usage and cost in the IC.

The techniques disclosed herein can reduce manufacturing test development efforts and provide at-speed frequency testing of memory circuits in an IC. In addition, the techniques disclosed herein can reduce design effort for an MBIST controller used to test memory circuits during power up of the IC. Also, the techniques disclosed herein can reduce circuit resources used for an MBIST controller and can make more resources in an IC available for other uses.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

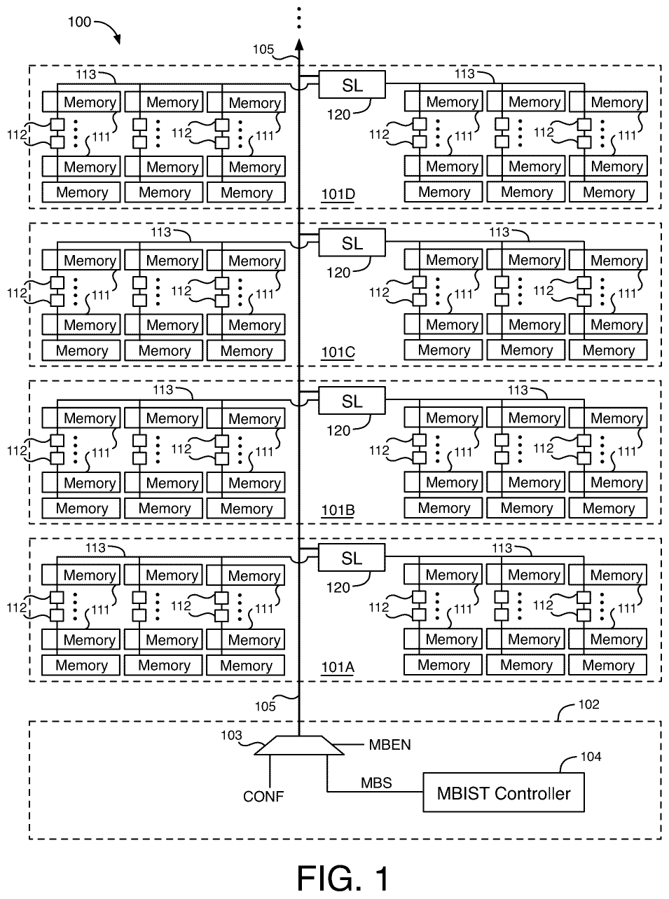

FIG. 1 is a diagram that illustrates an example of a portion of an integrated circuit (IC) 100 that can test memory circuits in the IC using a memory built-in-self-test (MBIST) controller circuit and a network-on-chip (NOC) bus. Integrated circuit (IC) 100 includes sectors 101 of configurable logic and memory circuits, a network-on-chip (NOC) bus 105, and a local sector manager (LSM) control circuit 102 (also referred to herein as control circuit 102).

Four sectors 101A, 101B, 101C, and 101D are shown in FIG. 1 merely as an example. According to various examples, IC 100 can include any number of sectors 101. Each of the sectors 101 in IC 100 includes a selector (SL) circuit 120, memory circuits 111, pipeline register circuits 112, and memory busses 113 coupled as shown in Figure (FIG. 1. Each of the memory circuits 111 can, for example, include a memory array having rows and columns of memory cells. The control circuit 102 includes a multiplexer circuit 103 and a memory built-in-self-test (MBIST) controller circuit 104.

IC 100 can be any type of integrated circuit, such as a configurable IC (e.g., a field programmable gate array (FPGA) or programmable logic device), a microprocessor IC, a graphics processing unit IC, a memory IC, an application specific IC, a transceiver IC, etc. In the examples described below, IC 100 is a configurable IC, such as an FPGA or programmable logic device (PLD).

According to the example in which IC 100 is a configurable IC, control circuit 102 can be used for controlling configuration bits in a configuration mode of the IC 100. In the configuration mode of the IC 100, multiplexer circuit 103 is configured by select signal MBEN to transmit configuration bits CONF to NOC bus 105. NOC bus 105 transmits the configuration bits CONF from multiplexer circuit 103 to the selector circuits 120 in the sectors 101A, 101B, 101C, 101D, etc. The selector circuits 120 then transmit the configuration bits (e.g., decoded configuration bits) to the memory circuits 111 and the configurable logic circuits (not shown in FIG. 1) in the respective sectors 101. The memory circuits 111 and the configurable logic circuits are then configured by the configuration bits.

After the configuration mode of IC 100 is completed, IC 100 enters a memory built-in-self-test (MBIST) mode. In the MBIST mode, the MBIST controller circuit 104 is enabled (e.g., by Joint Test Action Group (JTAG) signals) to generate MBIST signals MBS. Also, during the MBIST mode, the state of the select signal MBEN is changed to cause the multiplexer circuit 103 to transmit the MBIST signals MBS to the NOC bus 105. The NOC bus 105 transmits the MBIST signals MBS from multiplexer circuit 103 to the selector circuits 120 in the sectors 101A, 101B, 101C, 101D, etc. The selector circuits 120 then transmit the MBIST signals MBS through busses 113 and through the pipeline register circuits 112 to the memory circuits 111 in the respective sectors 101. Thus, the NOC bus 105 and the busses 113 are overridden by the MBIST signals MBS during the MBIST mode. The MBIST signals MBS can be transmitted through busses 113 and pipeline register circuits 112 to every memory circuit 111 in a sector. By using the NOC bus 105 for transmitting both configuration bits and the MBIST signals, additional routing paths are not needed in IC 100 to transmit the MBIST signals to the memory circuits 111, which reduces IC die area and reduces the complexity of signal routing.

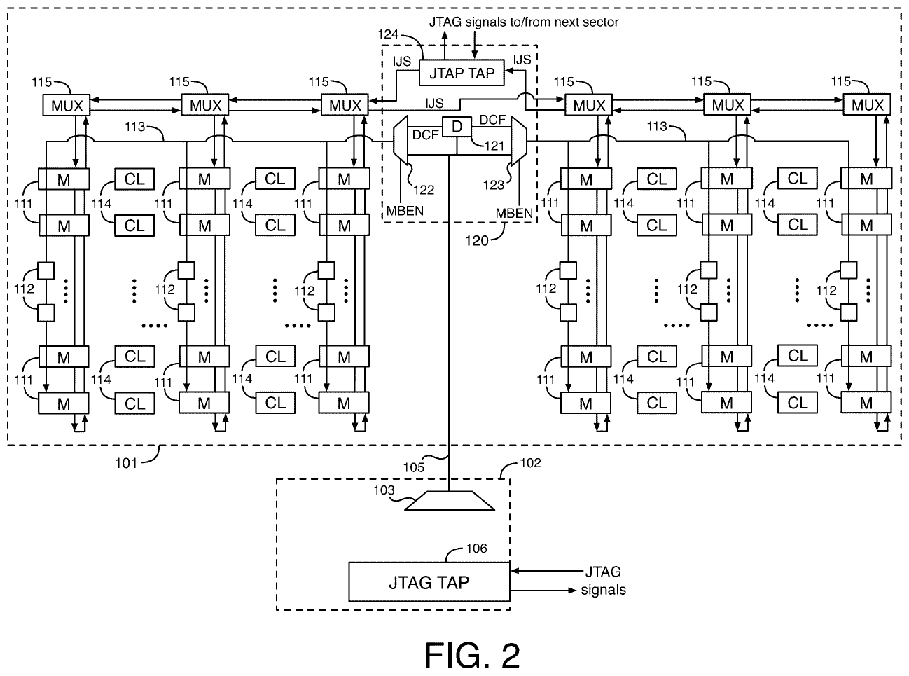

FIG. 2 is a diagram that illustrates further details of circuits in a sector 101 and the control circuit 102 in IC 100. FIG. 2 illustrates examples of circuits that can be in each of the sectors 101A, 101B, 101C, 101D, etc. in IC 100. As shown in FIG. 2, each sector 101 can include memory circuits 111, pipeline register circuits 112, memory busses 113, configurable logic (CL) circuits 114, and multiplexer (MUX) circuits 115 that are coupled as shown in FIG. 2. The selector circuit 120 includes a decoder circuit 121, two multiplexer circuits 122 and 123, and a Joint Test Action Group (JTAG) Test Access Port (TAP) controller circuit 124. In FIG. 2, the control circuit 102 also includes a JTAG TAP controller circuit 106 that generates and receives JTAG signals.

In the configuration mode of the IC 100, multiplexer circuit 103 is configured to transmit configuration bits through NOC bus 105 to the decoder circuit 121 in selector circuit 120. The decoder circuit 121 decodes the configuration bits to generate decoded configuration bits DCF. In configuration mode, the multiplexer circuits 122-123 are configured to provide the decoded configuration bits DCF through busses 113 (and other routing) to the memory circuits 111 and the configurable logic circuits 114 on each side of the selector circuit 120. The memory circuits 111 and the configurable logic circuits 114 are then configured by the decoded configuration bits.

In IC 100, JTAG signals from JTAG pads (i.e., external terminals of the IC) are routed to every sector 101 in IC 100. The JTAG signals can include, for example, Test Clock (TCK), Test Mode Select (TMS), Test Data In (TDI), and Test Data Out (TDO). The JTAG signals are then daisy chained from one sector 101 to another sector 101. Within a sector 101, the JTAG TAP controller circuit 124 generates internal Joint Test Action Group (IJTAG) signals IJS using the JTAG signals.

The IJTAG signals IJS set the MBIST mode. For example, the IJTAG signals IJS can configure multiplexer circuit 103 to transmit the MBIST signals MBS from MBIST controller circuit 104 to NOC bus 105 during the MBIST mode. Also, the IJTAG signals IJS can configure the multiplexer circuits 122-123 to transmit the MBIST signals MBS from NOC bus 105 to memory circuits 111 through busses 113 during MBIST mode.

The IJTAG signals IJS are transmitted from the JTAG TAP controller circuit 124 to every memory circuit 111 in the sector 101 through the multiplexer circuits 115 during the MBIST mode. In addition, IJTAG signals IJS can be transmitted from the memory circuits 111 through multiplexer circuits 115 to the JTAG TAP controller circuit 124 in MBIST mode. For example, the IJTAG signals IJS can carry out sticky error bits from comparator circuits in each memory circuit 111 through JTAG TAP controller circuit 124 to the JTAG pads to perform a pass/fail determination for a memory test of each memory circuit 111.

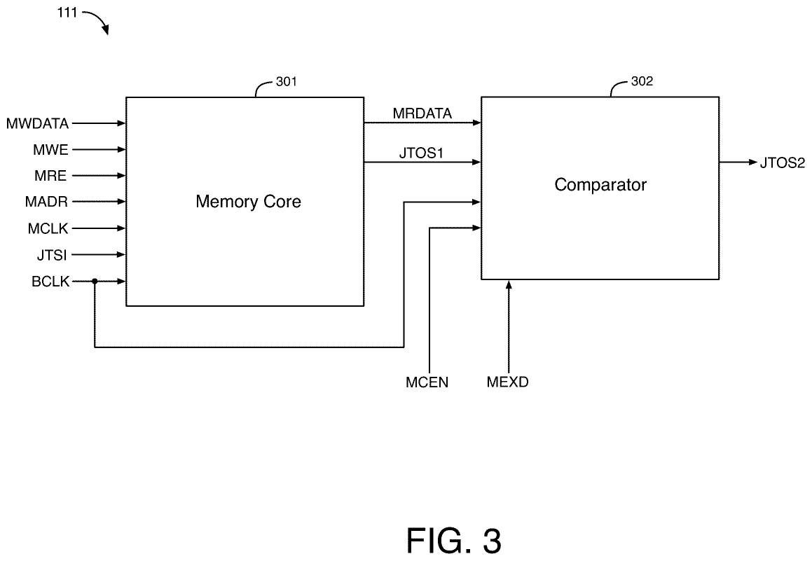

FIG. 3 is a diagram that illustrates examples of a memory core circuit 301 and comparator circuits 302 that can be in each of the memory circuits 111 in the sectors 101 of integrated circuit (IC) 100. In the example of FIG. 3, memory core circuit 301 and comparator circuits 302 are in every memory circuit 111 in IC 100. The memory core circuit 301 can, for example, include a memory array of memory storage cells.

During MBIST mode, MBIST signals, including signals MWDATA (including write data), MWE (write enable), MRE (read enable), MADR (address signals), MCLK (MBIST clock signal), JTSI (JTAG input signals), and BCLK (built-in-self-test clock signal) from bus 113 are provided to memory core circuit 301. The MBIST signals MWDATA, MWE, MRE, MADR, MCLK, JTSI, and BCLK overwrite the functional signals in memory core circuit 301 to perform read and write operations to the memory array in memory core circuit 301 when the MBIST mode is enabled by the IJTAG signals. The signals JTSI are transmitted through a bus via multiplexer circuits 115 to memory circuit 111 during the MBIST mode. The write data indicated by signals MWDATA is written to the memory array in memory core circuit 301 during a write operation. During a read operation in MBIST mode, the memory core circuit 301 reads the write data that was written during the write operation and outputs this data as read data in signals MRDATA.

The memory core circuit 301 outputs JTAG signals JTOS1 and the signals MRDATA that indicate the read data read from memory core circuit 301 during the read operation. Comparator circuits 302 compare the read data indicated by signals MRDATA with expected data indicated by signals MEXD to generate sticky error bits in response to an MBIST comparator enable signal MCEN. The expected data indicated by signals MEXD is generated by MBIST controller circuit 104. The sticky error bits generated by comparator circuits 302 may indicate mismatch errors between the read data indicated by signals MRDATA and the expected data indicated by signals MEXD.

The sticky error bits are output by the comparator circuits 302 as IJTAG signals JTOS2. The sticky error bits can be shifted out through multiplexer circuits 115 and JTAG TAP controller circuit 124 to the JTAG output pads to determine whether a memory test of the memory circuit 111 has passed or failed. In some examples, all of the memory circuits 111 receive MBIST signals concurrently. Also, the MBIST mode can be enabled independently in each memory circuit 111, so that all of the memory circuits 111 or a subgroup of the memory circuits 111 can be selected for testing. For custom circuit designs in an FPGA, this feature provides an option to test all of the memory circuits 111 or only selected memory circuits 111 that are used in the custom circuit design to be tested.

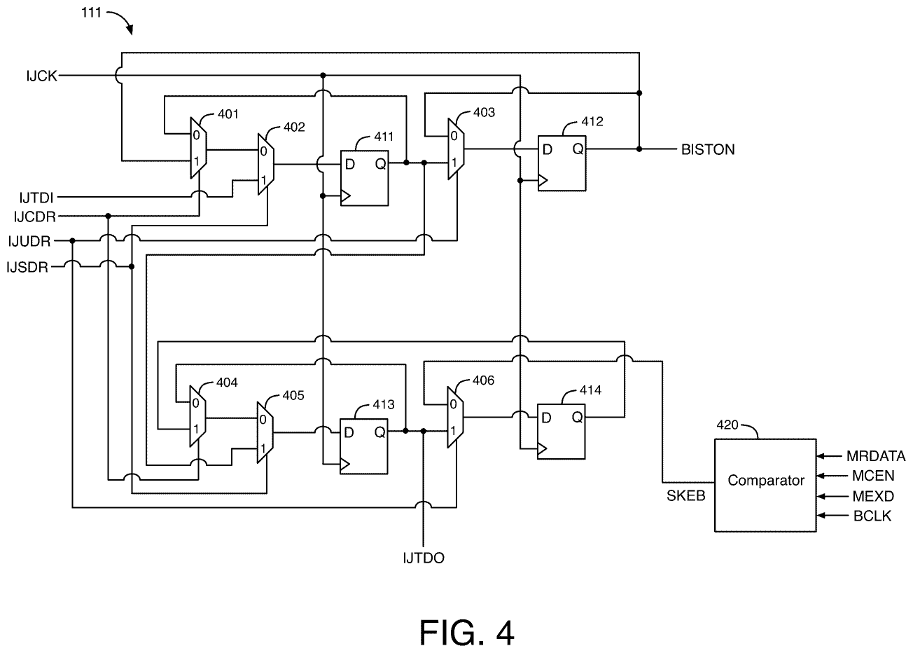

FIG. 4 is a diagram that illustrates details of examples of circuits that can be in each of the memory circuits 111 to enable a memory built-in-self-test (MBIST) during MBIST mode. In the example of FIG. 4, each memory circuit 111 includes 6 multiplexer circuits 401-406, 4 D flip-flop circuits 411-414, and a comparator circuit 420 that are coupled as shown in FIG. 4. IJTAG signals IJCK (clock signal), IJTDI (data in), IJCDR (capture data register), IJUDR (update data register), and IJSDR (shift data register) are provided to the memory circuit 111 as shown in FIG. 4. In addition, signals MRDATA, MCEN, MEXD, and BCLK are provided to comparator circuit 420.

In order to enable the MBIST mode, control signal IJSDR is set to a digital value of 1 and control signal IJUDR is set to a digital value of 0 to shift a digital 1 bit from data in signal IJTDI through multiplexer 402 to flip-flop circuit 411. Then, control signal IJSDR is set to a digital value of 0 and control signal IJUDR is set to a digital value of 1 to shift to shift the digital 1 bit from flip-flop circuit 411 through multiplexer circuit 403 to flip-flop circuit 412 in output signal BISTON. When signal BISTON is a digital 1, the IC 100 operates in the MBIST mode, and the multiplexer circuits 103 and 122-123 are configured to transmit the MBIST signals through NOC bus 105 and busses 113 to memory circuits 111.

The comparator circuit 420 compares one of the read data bits indicated by signals MRDATA with a corresponding expected data bit indicated by signals MEXD when the comparator circuit 420 is enabled by enable signal MCEN to generate a sticky error bit SKEB at an output. The comparator circuit 420 can also include a storage circuit that captures the sticky error bit SKEB at the output in response to clock signal BCLK. The comparator circuit 420 causes the sticky error bit SKEB to indicate whether the read data bit indicated by signals MRDATA matches the corresponding expected data bit indicated by signals MEXD. The comparator circuit 420 causes the sticky error bit SKEB to indicate any mismatch between the expected data bit and the read data bit from the memory core circuit 301 during a built-in-self-test.

The sticky error bit SKEB is provided to the 0 input of multiplexer circuit 406 as shown in FIG. 4. The sticky error bit SKEB can be shifted from comparator circuit 420 through the flip-flop circuits 413-414 to a JTAG output pad as is now described. In order to shift out the sticky error bit SKEB, control signals IJCDR, IJUDR, and IJSDR are set to digital values of 1, 0, and 0, respectively, to shift the sticky error bit SKEB from comparator circuit 420 through multiplexer 406, flip-flop circuit 414, multiplexer circuit 404, multiplexer circuit 405, and flip-flop circuit 413 as data output signal IJTDO. Thus, the sticky error bit SKEB is captured and shifted out through flip-flop circuits 414 and 413 as data output signal IJTDO (e.g., part of signals IJS), while the flip-flop circuits 411 and 413 are configured as a shift register. Subsequently, the sticky error bit SKEB is then directly shifted out to the JTAG output pad (TDO).

The process of testing memory circuits 111 in IC 100 can be summarized as follows. Through JTAG, the MBIST mode is enabled in the targeted memory circuits 111 to be tested. The MBIST mode is enabled in the selector circuits 120 for the sectors 101 in which the targeted memory circuits 111 reside. The MBIST mode is also enabled in MBIST controller circuit 104. Then, a wait period begins for the MBIST testing time. After the MBIST tests have been performed in the targeted memory circuits 111, an MBIST done status signal in MBIST controller circuit 104 is scanned out to confirm the MBIST tests are completed. Then, the sticky error bits generated by the targeted memory circuits 111 are shifted out through JTAG. The targeted memory circuits 111 are daisy chained to form a shift register, and the IJTAG sticky error bits are shifted out to the JTAG output pads. By calculating the shift out bit position, the pass/fail status of each targeted memory circuit 111 can be determined.

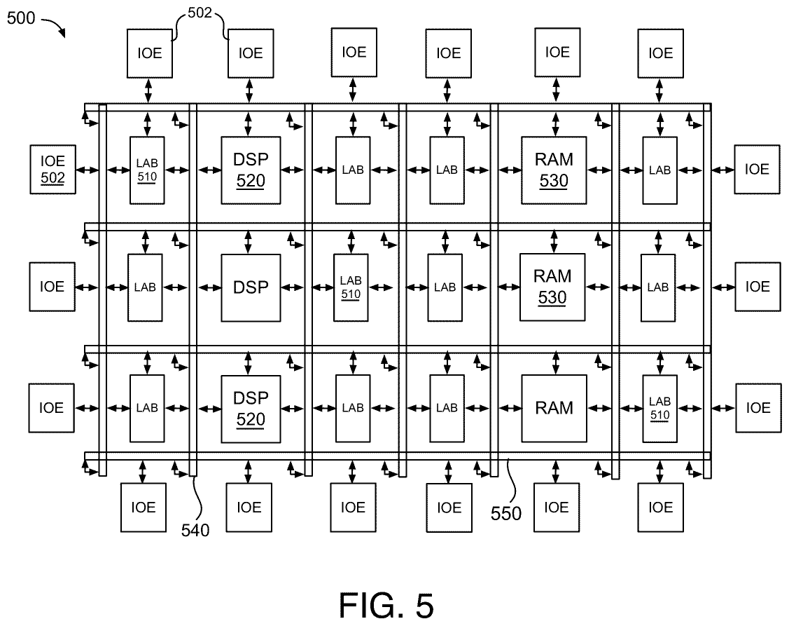

FIG. 5 illustrates an example of a configurable logic integrated circuit (IC) 500 that can include, for example, the circuitry disclosed herein with respect to any, some, or all of FIGS. 1, 2, 3, and/or 4. As shown in FIG. 5, the configurable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals. The configurable functional circuit blocks shown in FIG. 5 can, for example, be configured to perform the functions of any of the circuitry disclosed herein with respect to FIGS. 1-4. For example, memory circuits 111 can be RAM blocks 530.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein with respect to FIGS. 1-4 can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The configurable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

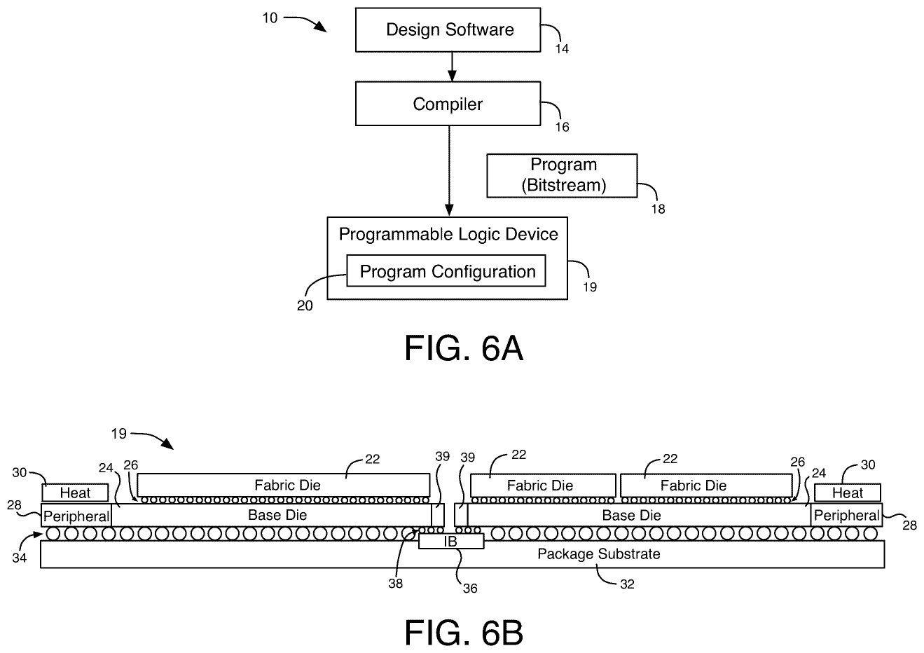

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

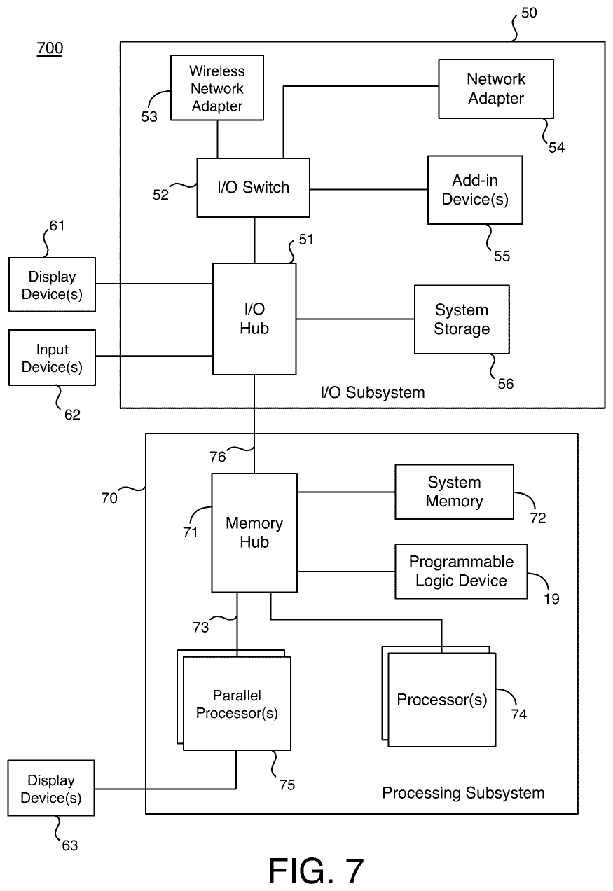

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an integrated circuit comprising: memory circuits; a selector circuit; a first bus coupled to the selector circuit; and a controller circuit to provide test signals from the controller circuit through the first bus to the selector circuit for transmission to the memory circuits during a memory built-in-self-test mode.

In Example 2, the integrated circuit of Example 1, wherein each of the memory circuits comprises a comparator circuit configurable to compare a read data bit read from one of the memory circuits to an expected data bit in the test signals to generate a sticky error bit during the memory built-in-self-test mode.

In Example 3, the integrated circuit of Example 2, wherein each of the memory circuits further comprises flip-flop circuits that are configurable to shift the sticky error bit to the selector circuit during the memory built-in-self-test mode.

In Example 4, the integrated circuit of any one of Examples 1-3, wherein the selector circuit comprises a test access port circuit configurable to receive and store test output bits generated by the memory circuits during the memory built-in-self-test mode.

In Example 5, the integrated circuit of any one of Examples 1-4, wherein the selector circuit comprises a first multiplexer circuit configurable to provide a first subset of the test signals through a second bus to a first subset of the memory circuits, and wherein the selector circuit further comprises a second multiplexer circuit configurable to provide a second subset of the test signals through a third bus to a second subset of the memory circuits.

In Example 6, the integrated circuit of any one of Examples 1-5 further comprising: multiplexer circuits configurable to provide control signals from the selector circuit to the memory circuits to perform built-in-self-tests during the memory built-in-self-test mode and to provide output signals generated by the memory circuits during the built-in-self-tests to the selector circuit.

In Example 7, the integrated circuit of any one of Examples 1-6, wherein each of the memory circuits comprises flip-flop circuits that are configurable to shift and store a bit used to enable a built-in-self-test of at least one of the memory circuits during the memory built-in-self-test mode.

In Example 8, the integrated circuit of any one of Examples 1-7, wherein the controller circuit provides write data to the memory circuits through the first bus and the selector circuit, and wherein the memory circuits store the write data as stored data, generate read data by reading the stored data, and compare the read data to expected data to generate sticky error bits during built-in-self-tests performed in the memory built-in-self-test mode.

In Example 9, the integrated circuit of any one of Examples 1-8, further comprising: a multiplexer circuit configurable to provide configuration bits through the first bus to the selector circuit for transmission to the memory circuits during a configuration mode of the integrated circuit.

Example 10 is a method for testing memory circuits in an integrated circuit, the method comprising: providing test signals from a controller circuit through a first bus to a first multiplexer circuit; configuring the first multiplexer circuit to provide the test signals from the first bus through a second bus to the memory circuits; and performing built-in-self-tests of the memory circuits using the test signals.

In Example 11, the method of Example 10, wherein performing the built-in-self-tests of the memory circuits further comprises comparing read data from the memory circuits to expected data to generate sticky error bits using comparator circuits in the memory circuits.

In Example 12, the method of any one of Examples 10-11 further comprising: generating test output bits in the memory circuits using the test signals; and shifting the test output bits to a control circuit through shift register circuits in the memory circuits and through second multiplexer circuits.

In Example 13, the method of any one of Examples 10-12, wherein performing the built-in-self-tests of the memory circuits further comprises storing write data indicated by the test signals in the memory circuits as stored data, accessing the stored data as read data, and comparing the read data to expected data to generate output test bits.

In Example 14, the method of any one of Examples 10-13 further comprising: configuring second multiplexer circuits to provide control signals from a test access port control circuit to the memory circuits to perform the built-in-self-tests and to provide test output bits generated by the memory circuits during the built-in-self-tests to the test access port control circuit.

In Example 15, the method of any one of Examples 10-14 further comprising: configuring a second multiplexer circuit to provide additional test signals from the first bus to additional memory circuits through a third bus; and performing additional built-in-self-tests of the additional memory circuits using the additional test signals.

In Example 16, the method of any one of Examples 10-15, wherein performing the built-in-self-tests of the memory circuits further comprises performing the built-in-self-tests using internal Joint Test Action Group signals generated by a control circuit.

Example 17 is a circuit system comprising: memory circuits; a first multiplexer circuit; first and second busses; and a memory controller circuit, wherein the first multiplexer circuit is configurable to provide test bits that are received from the memory controller circuit through the first bus to the memory circuits through the second bus for performing built-in-self-tests of the memory circuits.

In Example 18, the circuit system of Example 17, wherein each of the memory circuits comprises a comparator circuit that compares a read data bit to an expected data bit to generate a sticky error bit during the built-in-self-tests.

In Example 19, the circuit system of any one of Examples 17-18, wherein the test bits comprise write data, and wherein the memory circuits store the write data as stored data, generate read data from the stored data, and compare the read data to expected data to generate sticky error bits during the built-in-self-tests.

In Example 20, the circuit system of any one of Examples 17-19 further comprising: second multiplexer circuits configurable to provide control signals from a control circuit to the memory circuits to perform the built-in-self-tests and to provide output bits generated by the memory circuits to the control circuit in response to the control signals during the built-in-self-tests.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising:
memory circuits;
a selector circuit;
a first bus coupled to the selector circuit; and
a controller circuit to provide test signals from the controller circuit through the first bus to the selector circuit for transmission to the memory circuits during a memory built-in-self-test mode.

2. The integrated circuit of claim 1, wherein each of the memory circuits comprises a comparator circuit configurable to compare a read data bit read from one of the memory circuits to an expected data bit in the test signals to generate a sticky error bit during the memory built-in-self-test mode.

3. The integrated circuit of claim 2, wherein each of the memory circuits further comprises flip-flop circuits that are configurable to shift the sticky error bit to the selector circuit during the memory built-in-self-test mode.

4. The integrated circuit of claim 1, wherein the selector circuit comprises a test access port circuit configurable to receive and store test output bits generated by the memory circuits during the memory built-in-self-test mode.

5. The integrated circuit of claim 1, wherein the selector circuit comprises a first multiplexer circuit configurable to provide a first subset of the test signals through a second bus to a first subset of the memory circuits, and wherein the selector circuit further comprises a second multiplexer circuit configurable to provide a second subset of the test signals through a third bus to a second subset of the memory circuits.

6. The integrated circuit of claim 1 further comprising:
multiplexer circuits configurable to provide control signals from the selector circuit to the memory circuits to perform built-in-self-tests during the memory built-in-self-test mode and to provide output signals generated by the memory circuits during the built-in-self-tests to the selector circuit.

7. The integrated circuit of claim 1, wherein each of the memory circuits comprises flip-flop circuits that are configurable to shift and store a bit used to enable a built-in-self-test of at least one of the memory circuits during the memory built-in-self-test mode.

8. The integrated circuit of claim 1, wherein the controller circuit provides write data to the memory circuits through the first bus and the selector circuit, and wherein the memory circuits store the write data as stored data, generate read data by reading the stored data, and compare the read data to expected data to generate sticky error bits during built-in-self-tests performed in the memory built-in-self-test mode.

9. The integrated circuit of claim 1 further comprising:
a multiplexer circuit configurable to provide configuration bits through the first bus to the selector circuit for transmission to the memory circuits during a configuration mode of the integrated circuit.

10. A method for testing memory circuits in an integrated circuit, the method comprising:
providing test signals from a controller circuit through a first bus to a first multiplexer circuit;
configuring the first multiplexer circuit to provide the test signals from the first bus through a second bus to the memory circuits; and
performing built-in-self-tests of the memory circuits using the test signals.

11. The method of claim 10, wherein performing the built-in-self-tests of the memory circuits further comprises comparing read data from the memory circuits to expected data to generate sticky error bits using comparator circuits in the memory circuits.

12. The method of claim 10 further comprising:
generating test output bits in the memory circuits using the test signals; and
shifting the test output bits to a control circuit through shift register circuits in the memory circuits and through second multiplexer circuits.

13. The method of claim 10, wherein performing the built-in-self-tests of the memory circuits further comprises storing write data indicated by the test signals in the memory circuits as stored data, accessing the stored data as read data, and comparing the read data to expected data to generate output test bits.

14. The method of claim 10 further comprising:
configuring second multiplexer circuits to provide control signals from a test access port control circuit to the memory circuits to perform the built-in-self-tests and to provide test output bits generated by the memory circuits during the built-in-self-tests to the test access port control circuit.

15. The method of claim 10 further comprising:
configuring a second multiplexer circuit to provide additional test signals from the first bus to additional memory circuits through a third bus; and
performing additional built-in-self-tests of the additional memory circuits using the additional test signals.

16. The method of claim 10, wherein performing the built-in-self-tests of the memory circuits further comprises performing the built-in-self-tests using internal Joint Test Action Group signals generated by a control circuit.

17. A circuit system comprising:
memory circuits;
a first multiplexer circuit;
first and second busses; and
a memory controller circuit, wherein the first multiplexer circuit is configurable to provide test bits that are received from the memory controller circuit through the first bus to the memory circuits through the second bus for performing built-in-self-tests of the memory circuits.

18. The circuit system of claim 17, wherein each of the memory circuits comprises a comparator circuit that compares a read data bit to an expected data bit to generate a sticky error bit during the built-in-self-tests.

19. The circuit system of claim 17, wherein the test bits comprise write data, and wherein the memory circuits store the write data as stored data, generate read data from the stored data, and compare the read data to expected data to generate sticky error bits during the built-in-self-tests.

20. The circuit system of claim 17 further comprising:
second multiplexer circuits configurable to provide control signals from a control circuit to the memory circuits to perform the built-in-self-tests and to provide output bits generated by the memory circuits to the control circuit in response to the control signals during the built-in-self-tests.
